(19) United States
(12) Patent Application Publication
(10) Pub. No.: US 2005/0000405 A1
(43) Pub. Date: Jan. 6, 2005

(54) Celebration diamond having dome-shaped crown with pavilion

(76) Inventor: Michael D. Brookshire, Phoenix, AZ (US)

Correspondence Address: QUARLES & BRADY LLP, RENAISSANCE ONE, TWO NORTH CENTRAL AVENUE, PHOENIX, AZ, 85004-2391, US

(21) Appl. No.: 10/671,842

(22) Filed: Sep. 25, 2003

Related U.S. Application Data
(63) Continuation-in-part of application No. 10/613,281, filed on Jul. 3, 2003.

(51) Int. Cl. C30B 7/00; C30B 21/02; C30B 28/06

(52) U.S. Cl. 117/68

(57) ABSTRACT

A diamond has a pavilion (22) with a plurality of facets (32) disposed from a girdle (26) to a culet (34). A dome-shaped crown (24) is disposed above the girdle. The dome-shaped crown has a plurality of rows of facets (40, 42) cut with a plurality of monotonically decreasing angles to form a stepped contour from the girdle to an apex of the dome-shaped crown. A star-shaped top-center facet is disposed at the apex of the crown. The facets of the pavilion are symmetrically disposed and extend continuous from the girdle to the culet. The plurality of sets of facets in the crown from the girdle to the apex of the crown are cut with monotonically decreasing angles, such as 90, 75, 65, 55, 45, 35, 30, 25, 20, 15, and 10 degrees, respectively.

### CROSS-REFERENCE TO RELATED APPLICATIONS

The present patent application is a continuation-in-part of, and claims priority to, co-pending U.S. application Ser. No. 10/613,281, filed on Jul. 3, 2003 by Michael D. Brookshire.

### FIELD OF THE INVENTION

The present invention relates in general to designs of precious stones and, more particularly, to a cut gemstone having a dome-shaped crown with a pavilion.

### BACKGROUND OF THE INVENTION

Precious stones, such as diamonds and other gemstones, are highly prized and valuable articles of manufacture. Gemstones are given and received for special occasions and important recognition, such as engagements, anniversaries, graduations, and other meaningful expressions of love, devotion, and accomplishment. Gemstones are mounted and worn in rings, necklaces, bracelets, pennants, earrings, and other jewelry. Gemstones have also been mounted to articles of clothing, watches, and any item where the user wants to convey a sense of beauty, style, originality, and special meaning.

The beauty of the gemstone is determined by its inherent physical and optical properties in combination with the alterations made to the stone in order to improve the display of these properties. Accordingly, the aesthetic appeal of the gemstone is often enhanced through polishing and/or cutting. While the aesthetic benefits of polishing are self evident, the advantages to be gained by gem cutting may not be readily apparent to most persons outside the field of gemology. However, most if not all observers can appreciate the final physical and optical characteristics brought out in a well-cut gemstone.

The gem cutter's craft involves cutting a stone at different angles relative to a predetermined plane to produce a series of flat surfaces, known as facets, on the gemstone. Most consumers of precious stones are familiar with the basic so-called “brilliant-cut” diamond as it is one of the more common cut gemstones available in the marketplace. As shown in FIG. 1, there are three general sections or portions that form the brilliant-cut gemstone as known in the prior art: the crown (top portion), the girdle (middle portion), and the pavilion (bottom portion). The girdle is the narrow rim that separates the crown from the pavilion. Moreover, the girdle is the section with the largest diameter of any part of the stone. On the very bottom of the pavilion there is a pointed tip called the culet. The large, flat facet on top of the crown is called the table.

The optical appeal of the gemstone, especially for diamonds, is largely measured in terms of its brilliance, shine, and scintillation, i.e. the flashing or sparkling that occurs when the gemstone and/or observer changes viewing angle. Brilliance can be explained in terms of externally and internally reflected light. Referring again to FIG. 1, when rays of light hit the crown of the gemstone, some light rays are reflected away while others enter the gemstone through the table. Most of the light rays that enter the gemstone are directed toward the pavilion. Once the light rays strike the pavilion, it is reflected inward again. Ultimately, the light rays exit the gemstone after reaching the crown again and, in combination with the externally reflected light, are perceived by the observer as enhanced brilliance. The degree of total reflection that takes place depends in part on the angle of the pavilion facets. Scintillation depends primarily on the size of the gemstone, the number of facets, and the angles of the facets. Generally speaking, the more facets of different angles present on the gemstone, the more scintillation can be expected.

In the prior art, gem cutters have found ways to increase the brilliance and scintillation of gemstones, particularly diamonds, by experimenting with various designs that involve different numbers of facets, different facet orientation, and different facet angles. The traditional brilliant-cut diamond may include 58 facets, 24 of which are disposed in the pavilion. In U.S. Pat. No. 3,286,486, a gemstone is disclosed having a pavilion with 72 facets. The increased number of facets in the pavilion and the different angles at which many of them are cut result in enhanced light reflection. Other improvements, such as found in U.S. Pat. No. 3,788,097, have involved making the number of mid-level pavilion facets an odd number, rather than the standard even number of facets, and further by cutting facets at different angles and arrangements, see U.S. Pat. No. 6,449,985.

In addition to improving brilliance and scintillation, it has been thought that simple geometric effects, e.g. approximating the look of a chrysanthemum, may produce desirable results when cut into gemstones. Thus, in some of these cuts, the facets are arranged to approximate natural curves, such as the petals of a flower. A few examples of such cuts can be found in “Diagrams For Faceting”, Volume II, by Glenn & Martha Vargas. However, elaborate geometric effects can also detract from brilliance and scintillation as the static image, e.g. the flower, effects how light is reflected and can distract the viewer.

### SUMMARY OF THE INVENTION

In one embodiment, the present invention is a diamond comprising a pavilion having a plurality of facets disposed from a girdle to a culet. A dome-shaped crown is disposed above the girdle. The dome-shaped crown has sets of facets cut with monotonically decreasing angles to form a stepped contour from the girdle to an apex of the dome-shaped crown. While the contour is generally curved to create the dome shape, the contour is achieved with a plurality of steps from each of the facets. Each step in the contour is determined by the angled cut of the facet.

In another embodiment, the present invention is a cut gemstone comprising a pavilion extending from a girdle to a culet. A crown has a first set of facets disposed above the girdle and a second set of facets disposed between the first set of facets and an apex of the crown. The first set of facets is cut at a first angle with respect to a reference line which is tangential to the apex of the crown and the second set of facets is cut at a second angle with respect to the reference line which is less than the first angle.

In another embodiment, the present invention is a cut gemstone comprising a pavilion having a plurality of facets disposed from a girdle to a culet. A dome-shaped crown is disposed above the girdle. The dome-shaped crown has a stepped contour from the girdle to an apex of the dome-shaped crown.

In another embodiment, the present invention is a method of cutting the crown of a gemstone having a center facet, a girdle, and a pavilion comprising the steps of forming a plurality of facets on the pavilion from a girdle to a culet, and forming a dome-shaped crown above the girdle. The dome-shaped crown has a stepped contour from the girdle to an apex of the dome-shaped crown.

### BRIEF DESCRIPTION OF THE DRAWINGS

FIG. 1 illustrates a brilliant-cut gemstone known in the prior art;

FIG. 2 illustrates a gemstone with a first row or set of facets formed in the rough crown;

FIG. 3 illustrates a bottom-view of the pavilion;

FIG. 4 illustrates the gemstone with first and second rows of facets formed in the rough crown;

FIG. 5 illustrates the gemstone with several sets of facets formed in the dome-shaped crown;

FIG. 6 illustrates first and second rows of facets formed between the girdle and apex of the dome-shaped crown;

FIG. 7 illustrates a gemstone with an oval dome-shaped crown;

FIG. 8 illustrates a gemstone with an alternate orientation of the sets of facets formed in the dome-shaped crown;

FIG. 9 illustrates a top-view of the dome-shaped crown of FIG. 8; and

FIG. 10 illustrates an alternative top-center facet of the dome-shaped crown.

### DETAILED DESCRIPTION OF THE DRAWINGS

Precious stones, such as diamonds and other gemstones, are naturally occurring materials found in selected areas of the world. The gemstones are mined or otherwise removed from the ground in rough form. Sometimes gemstones can be found in rivers and streams. Gemstones exhibits physical and optical properties such as hardness, reflection, refraction, and granular structure. The rare nature of these gemstones makes them highly prized, valuable, and ideal for refining and setting into rings, necklaces, bracelets, pennants, earrings, and other jewelry. Gemstones have also been mounted to articles of clothing, watches, and any item where the user wants to convey a sense of beauty, style, originality, and special meaning.

In its rough form, gemstones come in a variety of shapes. The octahedron is shaped like two pyramids mounted base-to-base with 8 sides and 12 points. The dodecahedron is similar to octahedron except with rounded points. Rough gemstones can be cut into a number of designs. The finish cut is selected by the gem cutter with consideration of the overall shape of the rough stone and how the grain structure lays. Economics and time constraints dictate that gem cutters generally want to minimize the waste, i.e. the part of the stone that is cut away, in selecting the final design.

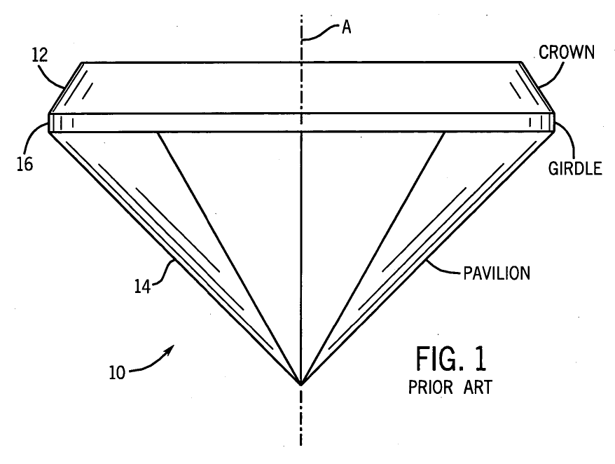

Referring to FIG. 1, gemstone 10 of the prior art is portrayed to outline the basic portions of a brilliant-cut gemstone. As shown, the gemstone has a crown or upper portion 12, a pavilion or lower portion 14, and a girdle or intermediate portion 16 between crown 12 and pavilion 14. The crown and the pavilion face in opposite directions. Gemstone 10 also has a central longitudinal axis A which constitutes an axis of symmetry around which the facets on pavilion 14 and crown 12 are disposed.

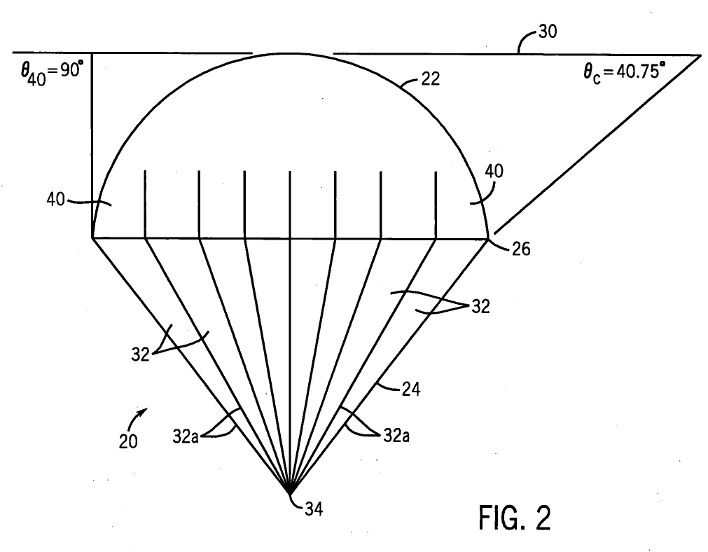

In FIG. 2, a side view of gemstone 20 is shown. In one embodiment, gemstone 20 is a diamond. The diamond rough can be almost any size and shape; however, a dodecahedron rough stone is selected for gemstone 20 because its natural form and characteristics are closer and more conducive to the final dome-shaped cut. Gemstone 20 comes from a rough stone which is conducive to forming a dome-shaped top portion or crown 22 and a conical-shaped portion or pavilion 24. A girdle 26 is designated at the common portion between crown 22 and pavilion 24. The rough stone will have larger dimensions than shown in FIG. 2.

In general, the process of cutting gemstone 20 involves placing the rough stone, such as a diamond rough, into a dop and then running the dop across a cutting wheel. The cutting wheel is made of cast iron or steel and balanced for high-speed rotation. A motor spins the cutting wheel at about 3000 rpm. The cutting wheel is prepared by depositing a diamond paste to the cutting wheel and grinding the diamond paste into the cutting wheel with a flat industrial diamond. The diamond paste is made of fine diamond dust mixed with olive oil. The diamond paste impregnates the surface of the cutting wheel and makes it a diamond cutting wheel. A diamond surface is required to cut diamond. A plurality of rings are formed on the diamond cutting wheel. In general, the outer rings do the cutting while the inner rings do the polishing on the gemstone rough.

The dop is a precision holder that clamps the diamond rough into a known position for cutting. The diamond must be cut perpendicular to its grain. There are many types of dops includes girdle dops for cutting the girdle, top dops for cutting the crown, and bottom dops for cutting the pavilion. The diamond is clamped in position in the dop. The dop is supported by a stand. The dop is rotated on a vertical axis, which coincides with the symmetry axis of the gem (similar to FIG. 1) by an indexing gear. In the present case, the indexing gear has 90 teeth which are assigned the indexes or numbers 1 to 90, respectively. When this gear indexes from one tooth to the next, the gear and the gemstone rotate through an angle of 1.0 degree. Thus, tooth 2 or index 2 represents an angle of rotation of 2.0 degrees; tooth 45 or index 45 an angle of rotation of 45 degrees, and so on.

The diamond as held by the dop is run across the surface of the diamond cutting wheel to cut the diamond. The orientation of the diamond, the angle of the cut, the length of the path across the cutting wheel, the pressure on the dop, and the experience and skill of the gem cutter, all contribute to the shape, size, and angle of the facet.

Gemstone 20 is cut with various angles which are measured from a plane or line normal to the axis of rotation of the gemstone. Since the gemstone is rotated about a vertical axis, the plane or line is horizontal. Moreover, it is common practice to define the very top of the crown as a horizontal plane or line, i.e. a zero degree angle, thereby providing a reference against which subsequent cuts are measured.

An imaginary reference line 30 is drawn tangential to the apex or top-most portion of crown 22. Reference line 30 is used to establish and cut the stone at the angles described below. A critical angle θ_{C}=40.75 degrees is established from reference line 30. Pavilion 24 is cut with sixteen facets 32 running from girdle 26 to culet 34. Facets 32 of pavilion 24 are each cut at the critical angle θ_{C}=40.75 degrees with respect to reference line 30. Facets 32 are cut and polished to attain an enhanced internal reflection of light rays.

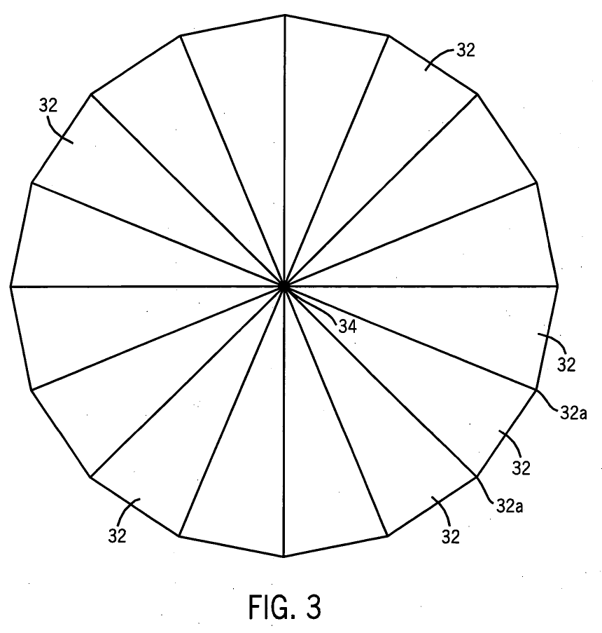

A bottom view of pavilion 24 and facets 32 is shown in FIG. 3. The sixteen facets 32 of pavilion 24 are uniformly and symmetrically disposed with respect to culet 34 around the circumference of gemstone 20. In other words, facets 32 extend radially inward from girdle 26 to culet 34 at the tip of pavilion 24. The sixteen facets 32 each have a continuous flat surface from girdle 26 to culet 34. The edges of neighboring facets 32 contact one another along common radial boundaries 32a.

Returning to FIG. 2, the process of forming dome-shaped crown 22 begins by cutting one or more viewing or examination facets in the diamond rough. The viewing facets allow the gem cutter to see into the stone and identify grain structures and imperfections. The gem cutter orients the rough and plans the cutting process to maximize the brilliance and symmetry of the final cut while minimizing the effect of any imperfection.

Once the diamond rough has been thoroughly evaluated and the gem cutter has a plan for the design of the final product, he or she begins by cutting a first row or set of facets 40 around crown 22 running from girdle 26 upward. The height the first set of facets 40 depends on the shape of the rough stone. In some designs, the width of facets 40 are selected such that there are sixteen facets 40 cut around the circumference of crown 22. Facets 40 are square or rectangular in form and cut θ₄₀40 =90° with respect to reference line 30. In one cutting method, the facets 40 are cut in opposing order. A first-cut facet 40 is cut θ₄₀=90° with respect to reference line 30 with the bottom edge of the facet common to girdle 26. The location of the first-cut facet 40 is a designer's choice, based on the gem cutter's evaluation of the stone. A second-cut facet 40 is cut also at θ₄₀=90° to reference line 30 with the bottom edge of the facet common to girdle 26. The location of the second-cut facet 40 is opposite the first-cut facet 40 to balance the cutting process. A third-cut facet 40 is cut 90° to reference line 30 with the bottom edge of the facet common to girdle 26 and located halfway between the first-cut facet 40 and second-cut facet 40. A fourth-cut facet 40 is cut 90 ° to reference line 30 with the bottom edge of the facet common to girdle 26 and located halfway between the first-cut facet 40 and second-cut facet 40, opposite the third-cut facet 40. The process of forming facets 40, halfway between already cut facets 40 and then forming the next facet 40 opposite the previously cut facet 40, continues until the first set of facets 40 is cut completely around gemstone 20 with their bottom edges common to girdle 26. FIG. 2 illustrates the first set of rectangular facets 40 cut into the diamond rough of gemstone 20. Again, at this point in the cutting process, the top portion of crown 22 is rough stone and will generally have a larger dimension than shown in FIG. 2. The dome-shape of crown 22 in FIG. 2 is illustrated for final effect. The facets 40 extend upward depending on the shape of the rough stone while maintaining the angle cut of θ₄₀=90°.

In an alternate method, the first set of facets 40 is cut in adjacent sequence. That is, the second-cut facet 40 is adjacent to the first-cut facet 40 and the third-cut facet 40 is adjacent to the second-cut facet 40, and so on until the first set of facets 40 is cut completely around gemstone 20 with their bottom edges common to girdle 26. Cutting the first set of facets 40 in adjacent sequence requires precision measuring tools or computer-controlled cutting machine in order to maintain the necessary spacing and consistency in facets 40.

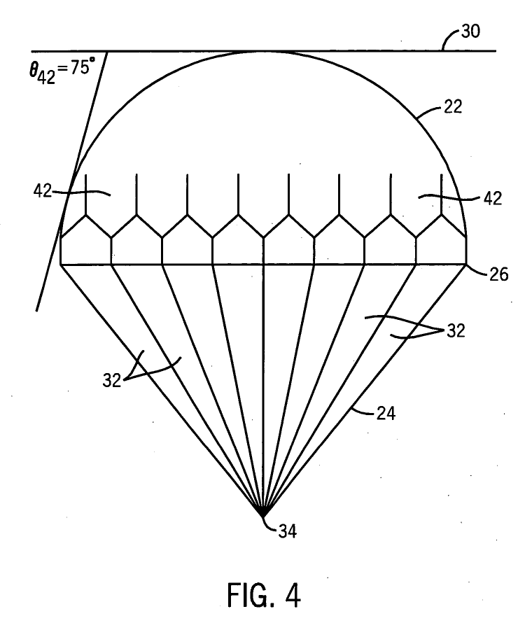

Once the first set of facets 40 is finished, a second row or set of facets 42 is cut above and offset from the first set of facets 40, see FIG. 4. Facets 42 are square or rectangular in form and cut θ₄₂=75° with respect to reference line 30. As described above, the second set of facets can be cut in opposing order, or in adjacent sequential order, by design choice. A first-cut facet 42 is cut θ₄₂=75° with respect to reference line 30 with the bottom edge of the facet centered about and overlapping the common side edges between two adjacent facets 40. The first-cut facet 42 results in a triangle shape being cut into the common side edges of the two adjacent facets 40 immediately below the first-cut facet 42. A second-cut facet 42 is cut with θ₄₂=75° to reference line 30 with the bottom edge of the facet centered about and overlapping the common side edges between two other adjacent facets 40. The process of forming the second set of facets 42, using the opposing order of cutting, or adjacent sequential order of cutting, continues until the second set of facets 42 is cut completely around crown 22 with their bottom edges common to the first set of facets 40. FIG. 4 illustrates the second set of rectangular facets 42 cut into the diamond rough of gemstone 20. Again, the uncut portions of the rough stone may have larger dimensions than shown in FIG. 4. The dome-shape of crown 22 in FIG. 4 is illustrated for final effect. The facets 42 extend upward depending on the shape of the rough stone while maintaining the angle cut of θ₄₀=75°.

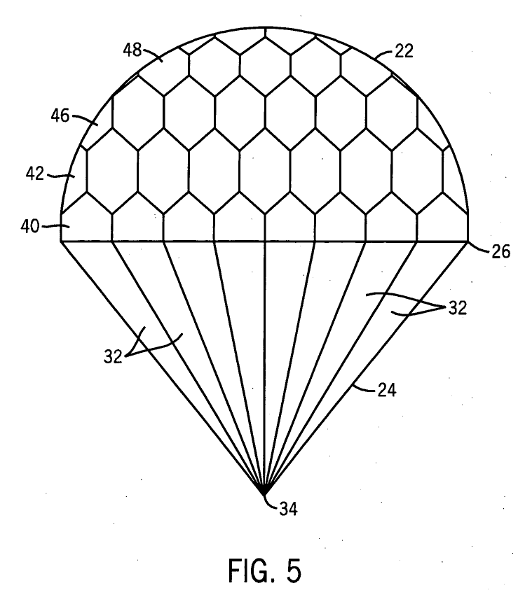

In FIG. 5, a third row or set of facets 44 is cut above and offset from the second set of facets 42 in a similar process as described for the second set of facets 42. Facets 44 are square or rectangular in form and cut 65° with respect to reference line 30. A fourth set of facets 46 is cut above and offset from the third set of facets 44. Facets 46 are square or rectangular in form and cut 55° with respect to reference line 30. A fifth set of facets 48 is cut above and offset from the fourth set of facets 46. Facets 48 are square or rectangular in form and cut 45° with respect to reference line 30. A sixth set of facets is cut above and offset from the fifth set of facets 48. The sixth set of facets are square or rectangular in form and cut 35° with respect to reference line 30. A seventh set of facets is cut above and offset from the sixth set of facets. The seventh set of facets are square or rectangular in form and cut 30° with respect to reference line 30. An eighth set of facets is cut above and offset from the seventh set of facets. The eighth set of facets are square or rectangular in form and cut 25° with respect to reference line 30. A ninth set of facets is cut above and offset from the eighth set of facets. The ninth set of facets are square or rectangular in form and cut 20° with respect to reference line 30. A tenth set of facets is cut above and offset from the ninth set of facets. The tenth set of facets are square or rectangular in form and cut 15° with respect to reference line 30. An eleventh set of facets is cut above and offset from the seventh set of facets. The eleventh set of facets are square or rectangular in form and cut 10° with respect to reference line 30. A final top-center facet is cut 0° with respect to reference line 30 at the apex of crown 22.

FIG. 5 illustrates several rows or sets of facets cut into the diamond rough of crown 22 on gemstone 20. Not all of the eleven rows or sets of facets described above are shown in FIG. 5 to simplify the drawing. The rows or sets of facets have monotonically decreasing angles, with respect to reference line 30, to form a generally curved contour from girdle 26 to the apex of crown 22. In reality the contour occurs in a series of steps as determined by the cut angle of the facets to give crown 22 its dome shape. Facets 32 provide a generally conical-shaped pavilion 24. The dome-shaped crown 22, especially in the case of a diamond, provides a fluid balance of light return from the numerous angles.

The size of the facets, orientation of the facets, number of rows or sets of facets, and cutting angles with respect to reference line 30 can be varied to create a variety of different dome-shaped designs. For example, more rows or sets of smaller facets can be used with smaller steps between cutting angles. Alternatively, fewer rows or sets of larger facets can be used with larger steps between cutting angles. Moreover, the size, shape, and angles of the facets can be used to vary the height of the dome in relation to the pavilion.

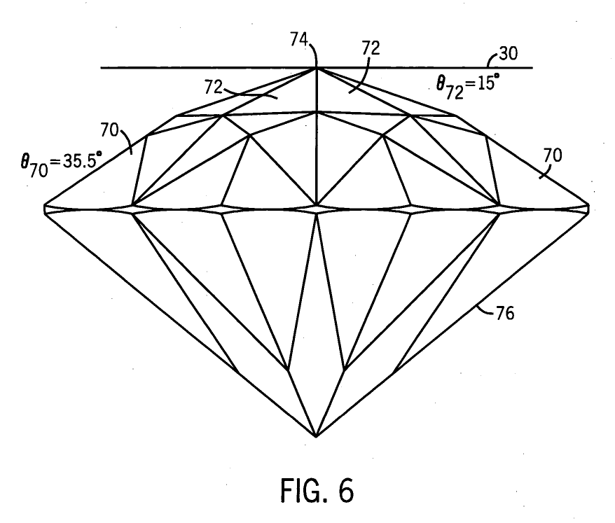

FIG. 6 illustrates a dome-shaped diamond, referred to as “rose-brilliant”, with two rows or sets of facets in the crown. The first set of facets 70 is cut θ₇₀=35.5° with respect to reference line 30. The second set of facets 72 is cut θ₇₂=15° with respect to reference line 30. Apex 74 is located at the top of the crown. Pavilion 76 is cut at the critical angle θ_{C}=40.75°. Pavilion 76 include eight main facets which are further cut into sixteen half-facets.

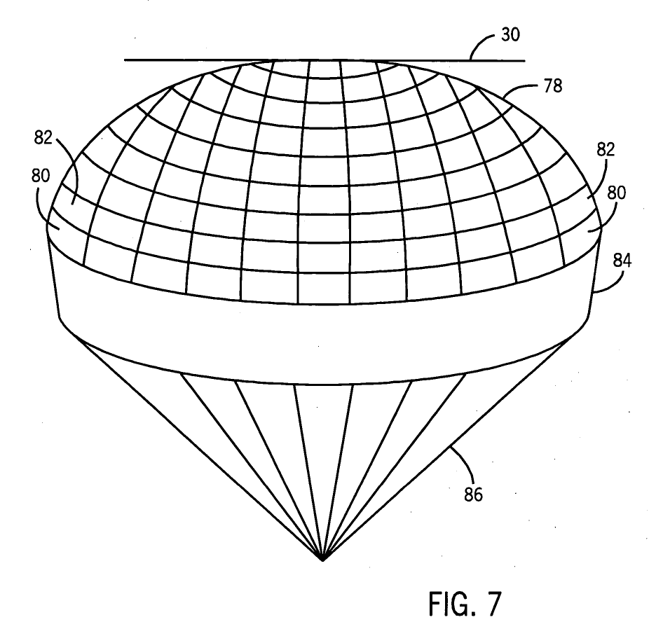

FIG. 7 illustrates another type of dome shape, this one having a generally oval-shaped crown 78. The first set of facets 80 is cut 90° to the reference line. The second set of facets 82 is step-cut, i.e. the second set of facets is cut directly above the first set of facets with the side edges of the first and second rows aligned. The remaining rows or sets of facets in crown 78 are also step cut to the apex of the crown. A girdle break 84 is used compensate for the non-circular shape of crown 78. Girdle break 84 is cut at angles ranging from 75° at the wide portion of the oval to 0° at the narrow portion of the oval. Pavilion 86 can then be cut at the critical angle 40.75° with respect to reference line 30 from girdle break 84. Pavilion 86 can be cut with main facets as shown in FIG. 3 or with half-facets as shown in FIG. 6.

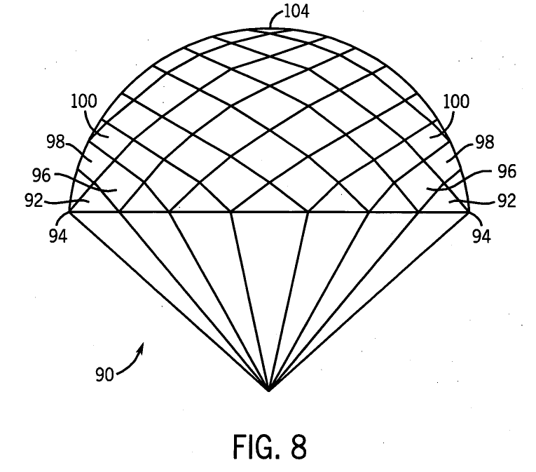

In FIG. 8, another dome-shaped gemstone 90 is shown. As is true for the various embodiments disclose herein, the gemstone can be a diamond. The first set of facets 92 is cut as triangles with bases common to girdle 94. The second set of facets 96 are cut as diamonds or parallelograms fitting between the first set of facets 92.

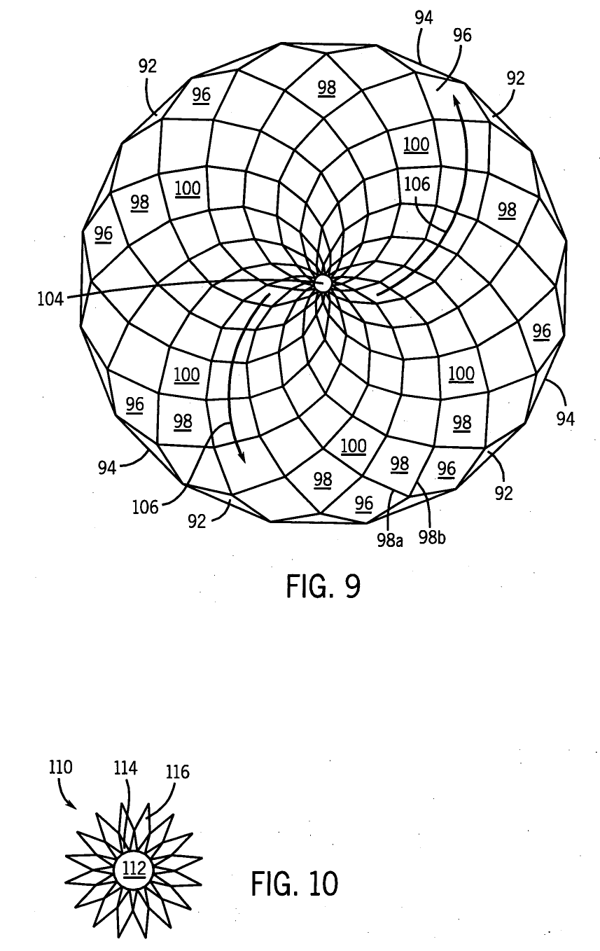

A top view of gemstone 90 is shown in FIG. 9. Neighboring facets are contiguous with one another up to the outer edge of each facet in the previous set of facets. The facets within a given set are all cut with the same angle. Starting with the set of facets 92 and working toward the top of gemstone 90, the rows or sets of facets are cut with 90°, 75°, 56°, 46°, 38°, 34°, 30°, 25°, and 19°, respectively. For example, the set of facets 96 are cut 75° to the reference line, the set of facets 98 are cut 56° to the reference line, the set of facets 100 are cut 46° to the reference line, and so on. The top-center facet 104 located at the apex of the crown is star-shaped as shown. The rows or sets of facets are concentrically disposed around gemstone 90. Each set contains sixteen individual facets, with each subsequent set contiguous with, and forming a ring around each previous set. The individual facets of each subsequent facet set is nested or disposed between two preceding facets. In other words, each individual facet of a given set share one edge with two facets from a preceding set. For example, a facet in set 98 shares edges 98a and 98b with two facets of set 96. Each set of facets grows larger as the cuts are made radially outward from the center facet to the outer periphery of the crown. Because subsequent facets are disposed or nested between two preceding facets, a spiraling effect as indicated by arrows 106 is created, giving the effect of the crown being in motion. By cutting such an arrangement or pattern of facets, the crown of the gemstone actually appears to radiate in a spiral fashion from the center facet at the top-center of the crown. It may be desirable to add to or subtract from the number of facets on the crown so that the spiraling effect and other optical properties can be optimized in accordance with individual stone characteristics, such as size, clarity, and color.

FIG. 10 illustrates an alternative arrangement to the top facet. The arrangement 110 includes a small ring or apex 112 and a set of triangular-shaped facets 114 surrounding ring 112. Another set of sixteen diamond-shaped facets 116 are cut between facets 114 at 15° angle.

In summary, the dome-shaped crown allows more light to received and reflected by the gemstone, thus providing greater the brilliance and scintillation. The gemstone has a much larger crown area due to the substitution of a very small center facet for the relatively large table that is found on prior art gems. The dome-shaped diamond has more crown facets, more variety of crown facet angles, and in some embodiments a unique spiraling effect.

A person skilled in the art will recognize that changes can be made in form and detail, and equivalents may be substituted, for elements of the invention without departing from the scope and spirit of the invention. The present description is therefore considered in all respects to be illustrative and not restrictive, the scope of the invention being determined by the following claims and their equivalents as supported by the above disclosure and drawings.

1. A diamond, comprising:
a pavilion having a plurality of facets disposed from a girdle to a culet; and
a dome-shaped crown disposed above the girdle, wherein the dome-shaped crown has sets of facets cut with monotonically decreasing angles to form a stepped contour from the girdle to an apex of the dome-shaped crown.

2. The diamond of claim 1, wherein each of the plurality of facets of the pavilion are symmetrically disposed and extend continuous from the girdle to the culet.

3. The diamond of claim 2, wherein the plurality of facets of the pavilion are each cut to an angle of about 40.75 degrees.

4. The diamond of claim 1, wherein the plurality of facets of the pavilion totals at least sixteen in number.

5. The diamond of claim 1, wherein the pavilion is substantially conical in shape.

6. The diamond of claim 1, wherein the apex of the crown includes a star-shaped top-center facet.

7. The diamond of claim 1, further including:
a first set of facets disposed in the crown adjacent to the girdle and cut about 90 degrees with respect to a reference line which is tangential to the apex of the dome-shaped crown; and
a second set of facets disposed in the crown adjacent to the first set of facets and cut about 75 degrees with respect to the reference line.

8. The diamond of claim 7, further including:
a third set of facets disposed in the crown adjacent to the second set of facets and cut about 65 degrees with respect to the reference line;
a fourth set of facets disposed in the crown adjacent to the third set of facets and cut about 55 degrees with respect to the reference line;
a fifth set of facets disposed in the crown adjacent to the fourth set of facets and cut about 45 degrees with respect to the reference line; and
a sixth set of facets disposed in the crown adjacent to the fifth set of facets and cut about 35 degrees with respect to the reference line.

9. The diamond of claim 8, further including:
a seventh set of facets disposed in the crown adjacent to the sixth set of facets and cut about 30 degrees with respect to the reference line;
an eighth set of facets disposed in the crown adjacent to the seventh set of facets and cut about 25 degrees with respect to the reference line;
a ninth set of facets disposed in the crown adjacent to the eighth set of facets and cut about 20 degrees with respect to the reference line;
a tenth set of facets disposed in the crown adjacent to the ninth set of facets and cut about 15 degrees with respect to the reference line; and
an eleventh set of facets disposed in the crown adjacent to the tenth set of facets and cut about 10 degrees with respect to the reference line.

10. The diamond of claim 7, further including:
a third set of facets disposed in the crown adjacent to the second set of facets and cut about 65 degrees with respect to the reference line;
a fourth set of facets disposed in the crown adjacent to the third set of facets and cut about 56 degrees with respect to the reference line;
a fifth set of facets disposed in the crown adjacent to the fourth set of facets and cut about 46 degrees with respect to the reference line; and
a sixth set of facets disposed in the crown adjacent to the fifth set of facets and cut about 38 degrees with respect to the reference line.

11. The diamond of claim 10, further including:
a seventh set of facets disposed in the crown adjacent to the sixth set of facets and cut about 34 degrees with respect to the reference line;
an eighth set of facets disposed in the crown adjacent to the seventh set of facets and cut about 30 degrees with respect to the reference line;
a ninth set of facets disposed in the crown adjacent to the eighth set of facets and cut about 25 degrees with respect to the reference line;
a tenth set of facets disposed in the crown adjacent to the ninth set of facets and cut about 19 degrees with respect to the reference line; and
an eleventh set of facets disposed in the crown adjacent to the tenth set of facets and cut about 15 degrees with respect to the reference line.

12. The diamond of claim 1, wherein ones of the facets disposed in the dome-shaped crown are rectangular.

13. A cut gemstone, comprising:
a pavilion extending from a girdle to a culet; and
a crown having a first set of facets disposed above the girdle and a second set of facets disposed between the first set of facets and an apex of the crown, wherein the first set of facets is cut at a first angle with respect to a reference line which is tangential to the apex of the crown and the second set of facets is cut at a second angle with respect to the reference line which is less than the first angle.

14. The cut gemstone of claim 13, wherein each of the plurality of facets of the pavilion are symmetrically disposed and extend continuous from the girdle to the culet.

15. The cut gemstone of claim 14 wherein each of the plurality of facets of the pavilion are cut to an angle of about 40.75 degrees with respect to the reference line.

16. The cut gemstone of claim 13, wherein the plurality of facets of the pavilion totals at least sixteen in number.

17. The cut gemstone of claim 13, wherein the apex of the crown includes a star-shaped facet.

18. The cut gemstone of claim 13, wherein the first set of facets is disposed in the crown adjacent to the girdle and cut about 90 degrees with respect to the reference line and the second set of facets is disposed in the crown adjacent to the first set of facets and cut about 75 degrees with respect to the reference line.

19. The cut gemstone of claim 18, further including:
a third set of facets disposed in the crown adjacent to the second set of facets and cut about 65 degrees with respect to the reference line;
a fourth set of facets disposed in the crown adjacent to the third set of facets and cut about 55 degrees with respect to the reference line;
a fifth set of facets disposed in the crown adjacent to the fourth set of facets and cut about 45 degrees with respect to the reference line; and
a sixth set of facets disposed in the crown adjacent to the fifth set of facets and cut about 35 degrees with respect to the reference line.

20. The cut gemstone of claim 19, further including:
a seventh set of facets disposed in the crown adjacent to the sixth set of facets and cut about 30 degrees with respect to the reference line;
an eighth set of facets disposed in the crown adjacent to the seventh set of facets and cut about 25 degrees with respect to the reference line;
a ninth set of facets disposed in the crown adjacent to the eighth set of facets and cut about 20 degrees with respect to the reference line;
a tenth set of facets disposed in the crown adjacent to the ninth set of facets and cut about 15 degrees with respect to the reference line; and
an eleventh set of facets disposed in the crown adjacent to the tenth set of facets and cut about 10 degrees with respect to the reference line.

21. The cut gemstone of claim 1, further including:
a third set of facets disposed in the crown adjacent to the second set of facets and cut about 65 degrees with respect to the reference line;
a fourth set of facets disposed in the crown adjacent to the third set of facets and cut about 56 degrees with respect to the reference line;
a fifth set of facets disposed in the crown adjacent to the fourth set of facets and cut about 46 degrees with respect to the reference line; and
a sixth set of facets disposed in the crown adjacent to the fifth set of facets and cut about 38 degrees with respect to the reference line.

22. The cut gemstone of claim 21, further including:
a seventh set of facets disposed in the crown adjacent to the sixth set of facets and cut about 34 degrees with respect to the reference line;
an eighth set of facets disposed in the crown adjacent to the seventh set of facets and cut about 30 degrees with respect to the reference line;
a ninth set of facets disposed in the crown adjacent to the eighth set of facets and cut about 25 degrees with respect to the reference line;
a tenth set of facets disposed in the crown adjacent to the ninth set of facets and cut about 19 degrees with respect to the reference line; and
an eleventh set of facets disposed in the crown adjacent to the tenth set of facets and cut about 15 degrees with respect to the reference line.

23. A cut gemstone, comprising:
a pavilion having a plurality of facets disposed from a girdle to a culet; and
a dome-shaped crown disposed above the girdle, wherein the dome-shaped crown has a stepped contour from the girdle to an apex of the dome-shaped crown.

24. The cut gemstone of claim 23, wherein each of the plurality of facets of the pavilion are symmetrically disposed and extend continuous from the girdle to the culet.

25. The cut gemstone of claim 24, wherein the plurality of facets of the pavilion are each cut to an angle of about 40.75 degrees with respect to the reference line which is tangential to the apex of the dome-shaped crown.

26. The cut gemstone of claim 23, wherein the apex of the dome-shaped crown includes a star-shaped facet.

27. The cut gemstone of claim 23, further including:
a first set of facets disposed in the crown adjacent to the girdle and cut about 90 degrees with respect to a reference line which is tangential to the apex of the dome-shaped crown; and
a second set of facets disposed in the crown adjacent to the first set of facets and cut about 75 degrees with respect to the reference line.

28. The cut gemstone of claim 27, further including:
a third set of facets disposed in the crown adjacent to the second set of facets and cut about 65 degrees with respect to the reference line;
a fourth set of facets disposed in the crown adjacent to the third set of facets and cut about 55 degrees with respect to the reference line;
a fifth set of facets disposed in the crown adjacent to the fourth set of facets and cut about 45 degrees with respect to the reference line; and
a sixth set of facets disposed in the crown adjacent to the fifth set of facets and cut about 35 degrees with respect to the reference line.

29. The cut gemstone of claim 28, further including:
a seventh set of facets disposed in the crown adjacent to the sixth set of facets and cut about 30 degrees with respect to the reference line;
an eighth set of facets disposed in the crown adjacent to the seventh set of facets and cut about 25 degrees with respect to the reference line;
a ninth set of facets disposed in the crown adjacent to the eighth set of facets and cut about 20 degrees with respect to the reference line;
a tenth set of facets disposed in the crown adjacent to the ninth set of facets and cut about 15 degrees with respect to the reference line; and
an eleventh set of facets disposed in the crown adjacent to the tenth set of facets and cut about 10 degrees with respect to the reference line.

30. The cut gemstone of claim 27, further including:
a third set of facets disposed in the crown adjacent to the second set of facets and cut about 65 degrees with respect to the reference line;
a fourth set of facets disposed in the crown adjacent to the third set of facets and cut about 56 degrees with respect to the reference line;
a fifth set of facets disposed in the crown adjacent to the fourth set of facets and cut about 46 degrees with respect to the reference line; and
a sixth set of facets disposed in the crown adjacent to the fifth set of facets and cut about 38 degrees with respect to the reference line.

31. The cut gemstone of claim 30, further including:
a seventh set of facets disposed in the crown adjacent to the sixth set of facets and cut about 34 degrees with respect to the reference line;
an eighth set of facets disposed in the crown adjacent to the seventh set of facets and cut about 30 degrees with respect to the reference line;
a ninth set of facets disposed in the crown adjacent to the eighth set of facets and cut about 25 degrees with respect to the reference line;
a tenth set of facets disposed in the crown adjacent to the ninth set of facets and cut about 19 degrees with respect to the reference line; and
an eleventh set of facets disposed in the crown adjacent to the tenth set of facets and cut about 15 degrees with respect to the reference line.

32. A method of cutting a gemstone, comprising:
forming a plurality of facets on a pavilion from a girdle to a culet; and
forming a dome-shaped crown above the girdle.

33. The method of claim 32, wherein the dome-shaped crown has a stepped contour from the girdle to an apex of the dome-shaped crown.

34. The method of claim 33, wherein the plurality of facets of the pavilion are each cut to an angle of about 40.75 degrees with respect to a reference line which is tangential to the apex of the dome-shaped crown.

35. The method of claim 33, further including:
forming a first set of facets in the crown adjacent to the girdle cut at an angle about 90 degrees with respect to a reference line which is tangential to the apex of the dome-shaped crown; and
forming a second set of facets in the crown adjacent to the first set of facets cut about 75 degrees with respect to the reference line.

36. The cut gemstone of claim 35, further including:
forming a third set of facets in the crown adjacent to the second set of facets cut about 65 degrees with respect to the reference line;
forming a fourth set of facets in the crown adjacent to the third set of facets cut about 55 degrees with respect to the reference line;
forming a fifth set of facets in the crown adjacent to the fourth set of facets cut about 45 degrees with respect to the reference line; and
forming a sixth set of facets in the crown adjacent to the fifth set of facets cut about 35 degrees with respect to the reference line.

37. The cut gemstone of claim 36, further including:
forming a seventh set of facets in the crown adjacent to the sixth set of facets cut about 30 degrees with respect to the reference line;
forming an eighth set of facets in the crown adjacent to the seventh set of facets cut about 25 degrees with respect to the reference line;
forming a ninth set of facets in the crown adjacent to the eighth set of facets cut about 20 degrees with respect to the reference line;
forming a tenth set of facets in the crown adjacent to the ninth set of facets cut about 15 degrees with respect to the reference line; and
forming an eleventh set of facets in the crown adjacent to the tenth set of facets cut about 10 degrees with respect to the reference line.

38. The cut gemstone of claim 35, further including:
forming a third set of facets in the crown adjacent to the second set of facets cut about 65 degrees with respect to the reference line;
forming a fourth set of facets in the crown adjacent to the third set of facets cut about 56 degrees with respect to the reference line;
forming a fifth set of facets in the crown adjacent to the fourth set of facets cut about 46 degrees with respect to the reference line; and
forming a sixth set of facets in the crown adjacent to the fifth set of facets cut about 38 degrees with respect to the reference line.

39. The cut gemstone of claim 38, further including:
forming a seventh set of facets in the crown adjacent to the sixth set of facets cut about 34 degrees with respect to the reference line;
forming an eighth set of facets in the crown adjacent to the seventh set of facets cut about 30 degrees with respect to the reference line;
forming a ninth set of facets in the crown adjacent to the eighth set of facets cut about 25 degrees with respect to the reference line;
forming a tenth set of facets in the crown adjacent to the ninth set of facets cut about 19 degrees with respect to the reference line; and
forming an eleventh set of facets in the crown adjacent to the tenth set of facets cut about 15 degrees with respect to the reference line.
